(19) United States
(12) Patent Application Publication
(10) Pub. No.: US 2006/0033549 A1
(43) Pub. Date: Feb. 16, 2006

(54) Level shifter

(76) Inventor: Chao-Sheng Huang, Hsin-Tien City (TW)

Correspondence Address: J C PATENTS, INC., 4 VENTURE, SUITE 250, IRVINE, CA, 92618, US

(21) Appl. No.: 11/111,089

(22) Filed: Apr. 20, 2005

(30) Foreign Application Priority Data
Aug. 10, 2004 (TW) 93123878

(51) Int. Cl. H03L 5/00

(52) U.S. Cl. 327/333

(57) ABSTRACT

A level shifter is provided, which is characterized by adding a PMOS transistor to each pair of NMOS and PMOS transistors in the conventional level shifter. Wherein, a first source/drain terminal and gate terminal of the added PMOS transistor are coupled to a second source/drain terminal and a gate terminal of the NMOS transistor, respectively. A second source/drain terminal of the added PMOS transistor is coupled to a first source/drain terminal of the PMOS transistor. When the NMOS transistor is turned on, the added PMOS transistor is turned off. Accordingly, the operation of the NMOS and PMOS transistors do not affect each other. As a result, the fighting effect can be avoided.

### CROSS-REFERENCE TO RELATED APPLICATION

This application claims the priority benefit of Taiwan application serial no. 93123878, filed on Aug. 10, 2004. All disclosure of the Taiwan application is incorporated herein by reference.

### BACKGROUND OF THE INVENTION

1. Field of the Invention

The present invention relates to a level shifter, and more particularly, to a level shifter for reducing signal interference.

2. Description of the Related Art

Level shifters transfer signals between domains with different voltages. For example, a level shifter transfers a signal operated in low-voltage integrated circuits, such as 1.2V, to high-voltage integrated circuits, such as 3.3V. When integrated circuits are operated under different voltages, the level shifter transfers a signal generated from an integrated circuit to another integrated circuit with different operational voltages.

FIG. 1 is a schematic drawing showing a conventional level shifter. With reference to FIG. 1, the input signal Lo is inputted via the input buffer 100. The input signal Lo varies within the range of the pre-shifting voltage VDDIN. The input buffer 100 comprises the series inverters 102 and 104. The input terminal of the inverter 102 receives the input signal Lo. The input terminal of the inverter 104 is coupled to the output terminal of the inverter 102. According to the input signal Lo, the buffer 100 generates the first buffer output signal Lo1 and the second buffer output signal Lo2, which is reverse to the first buffer output signal Lo1.

In addition, the conventional level shifter also comprises a first NMOS transistor 121, a first PMOS transistor 123, a second NMOS transistor 125 and a second PMOS transistor 127. The gate terminals of the first NMOS transistor 121 and the second NMOS transistor 125 receive the first buffer output signal Lo2 and the first buffer output signal Lo1, respectively. The first source/drain terminal of the first NMOS transistor 121 is grounded. The second source/drain terminal of the first NMOS transistor 121 is coupled to the first source/drain terminal of the first PMOS transistor 123, outputting the first level-shifting signal NT1. Further, the second source/drain terminal of the first PMOS transistor 123 is coupled to the post-shifting voltage VPPIN. The gate terminal of the first PMOS transistor 123 is coupled to the second source/drain terminal of the second NMOS transistor 125. The first source/drain terminal of the second NMOS transistor 125 is grounded. The second source/drain terminal of the second NMOS transistor 125 is coupled to the first source/drain terminal of the second PMOS transistor 127, outputting the second level-shifting signal NT2. The second source/drain terminal of the second PMOS transistor 127 is also coupled to the post-shifting voltage VPPIN. The gate terminal of the second PMOS transistor 127 is coupled to the second source/drain terminal of the first NMOS transistor 121. The post-shifting voltage VPPIN is higher than the pre-shifting voltage VDDIN.

When the input signal Lo is at low state, the buffer 100 outputs a first buffer output signal Lo1 being at high state, and a second buffer output signal Lo2 being at low state. The level of the first buffer output signal Lo1 is the pre-shifting voltage VDDIN. According to the first buffer output signal Lo1, the second NMOS transistor 125 is turned on. The turned-on second PMOS transistor 127 will fight with the turned-on second NMOS transistor 125, which is designed to have greater driving. As a result, the second level-shifting signal NT2 is pulled down to low state. The first PMOS transistor 123 is then turned on and the first level-shifting signal NT1 is pulled up to high state, which is in a level similar to that of the post-shifting voltage VPPIN. The second PMOS transistor 127 is turned off. Accordingly, the level of the first buffer output signal Lo1 is similar to that of the first level shifting signal NT1, which is transferred from the pre-shifting voltage VDDIN to the post-shifting voltage VPPIN.

If the input signal Lo is at high state, the first buffer output signal Lo1 is at low state, and the second buffer output signal Lo2 is at high state. According to the second buffer output signal Lo2, the first NMOS transistor 121 is turned on and the second NMOS transistor 125 is turned off. The turned-on first NMOS transistor 121 will fight with the turned-on first PMOS transistor 123. The first NMOS transistor 121 is designed to have a greater driving force. As a result, the first level-shifting signal NT1 is pulled down to low state. The second PMOS transistor 127 is then turned on, and the second level-shifting signal NT2 is pulled up high state. Then, the first PMOS transistor 123 is turned off. After the first NMOS transistor 121 is turned on, the first PMOS transistor 123 is turned on, too. This will bring about the fighting effect. The driving force to turn on the first NMOS transistor 121 has to be stronger than that of the first PMOS transistor 123 to pull down the first level-shifting signal NT1 to low-state while the level-shifting signal NT1 is at high-state. The same also applies to the second NMOS transistor 125 and the second PMOS transistor 127. However, if the level of the input signal Lo is unstable due to signal interference, the driving force to the first and the second NMOS transistors 121 and 125 will be altered. As a result, the transfer time of the first level-shifting signal NT1 and the second level-shifting signal NT2 jitters. Accordingly, the output signals also jitters.

### SUMMARY OF THE INVENTION

Accordingly, the present invention is directed to a level shifter, whose output signals generated from the level shifter are not altered with different operating voltages of the transistors.

The present invention is also directed to a level shifter, whose output signals are not disturbed by signal interference, to avoid the jitter effect.

The present invention provides a level shifter. The level shifter comprises a buffer circuit, a first NMOS transistor, a first PMOS transistor, a second PMOS transistor, a second NMOS transistor, a third PMOS transistor and a fourth PMOS transistor. The buffer circuit receives an input signal and outputs a first buffer output signal and a second buffer output signal, which is reverse to the first buffer output signal, wherein the first and the second buffer output signals vary within a range of a pre-shifting voltage. A gate terminal of the first NMOS transistor receives the second buffer output signal, and a first source/drain terminal of the first NMOS transistor is grounded. A gate terminal of the first PMOS transistor is coupled to the gate terminal of the first NMOS transistor. A first source/drain terminal of the first PMOS transistor is coupled to a second source/drain terminal of the first NMOS transistor, outputting a first level-shifting signal. A first source/drain terminal of the second PMOS transistor is coupled to a second source/drain terminal of the first PMOS transistor. A second source/drain terminal of the second PMOS transistor is coupled to a post-shifting voltage, which is not equal to the pre-shifting voltage. A gate terminal of the second NMOS transistor receives the first buffer output signal. A first source/drain terminal of the second NMOS transistor is grounded. A gate terminal of the third PMOS transistor is coupled to the gate terminal of the second NMOS transistor. A first source/drain terminal of the third PMOS transistor is coupled to a second source/drain terminal of the second NMOS transistor and the gate terminal of the second PMOS transistor, outputting a second level-shifting signal. Wherein, the first and the second level-shifting signals vary within a range of the post-shifting voltage. A first source/drain terminal of the fourth PMOS transistor is coupled to a second source/drain terminal of the third PMOS transistor. A second source/drain terminal of the fourth PMOS transistor is coupled to the post-shifting voltage. A gate terminal of the fourth PMOS transistor is coupled to the second source/drain terminal of the first NMOS transistor.

Accordingly, the level shifter of the present invention comprises the first and the third PMOS transistors, which pull down the first and the second level-shifting signals instantly. As a result, the pull-down difference of the first and the second level-shifting signals due to different turn-on conditions of the first and the second NMOS transistors can be avoided. The jitter effect, therefore, can also be prevented. In addition, the states of the first and the second level-shifting signals will not be altered by inputted signal interference.

The above and other features of the present invention will be better understood from the following detailed description of the embodiments of the invention that is provided in combination with the accompanying drawings.

### BRIEF DESCRIPTION OF THE DRAWINGS

FIG. 1 is a schematic drawing showing a conventional level shifter.

FIG. 2 is a cricuit drawing showing a level shifter according to an embodiment of the present invention.

FIG. 3 is a circuit drawing showing a buffer circuit according to an embodiment of the present invention.

FIG. 4A is a circuit drawing showing a first output buffer circuit according to an embodiment of the present invention.

FIG. 4B is a circuit drawing showing a second output buffer circuit according to an embodiment of the present invention.

### DESCRIPTION OF THE EMBODIMENT

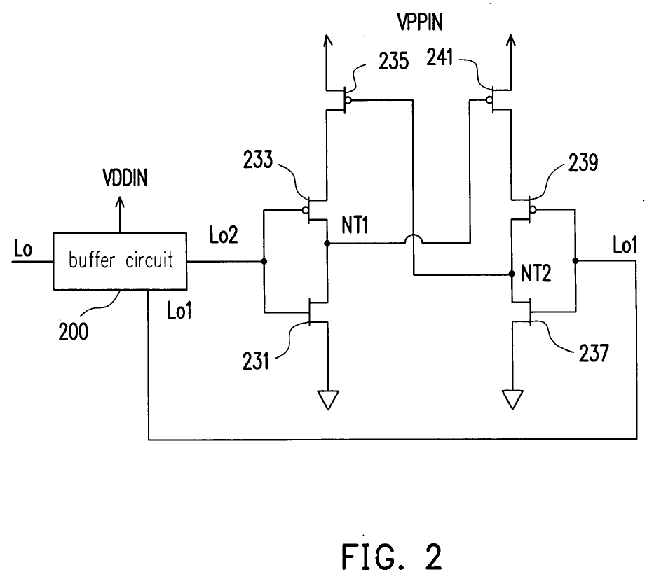

FIG. 2 is a circuit drawing showing a level shifter according to an embodiment of the present invention. With reference to FIG. 2, the buffer circuit 200 outputs the first buffer output signal Lo1 and the second buffer output signal Lo2 according to the input signal Lo. The first buffer output signal Lo1 and the second buffer output signal Lo2 are reverse to each other and vary within a range of pre-shifting voltage VDDIN, such as 1.2V.

With reference to FIG. 2, the gate terminal of the first NMOS transistor 231 receives the second buffer output signal Lo2. The first source/drain terminal of the first NMOS transistor 231 is grounded. The second source/drain terminal of the first NMOS transistor 231 is coupled to the first source/drain terminal of the first PMOS transistor 233, outputting the first level-shifting signal NT1. The gate terminal of the first PMOS transistor 233 is coupled to the gate terminal of the first NMOS transistor 231. The second source/drain terminal of the first PMOS transistor 233 is coupled to the first source/drain terminal of the second PMOS transistor 235. The second source/drain terminal of the second PMOS transistor 235 is coupled to the post-shifting voltage VPPIN, which is not equal to the pre-shifting voltage VDDIN. In this embodiment, the post-shifting voltage VPPIN, such as 3.3V, is higher than the pre-shifting voltage VDDIN. In addition, the first source/drain terminal of the second NMOS transistor 237 is grounded, too. The gate terminal of the second NMOS transistor 237 receives the first buffer output signal Lo1. The second source/drain terminal of the second NMOS transistor 237 is coupled to the gate terminal of the second PMOS transistor 235, outputting the second level-shifting signal NT2. The first source/drain terminal and the gate terminal of the third PMOS transistor 239 are coupled to the second source/drain terminal and the gate terminal of the second NMOS transistor 237, respectively. The first source/drain terminal and the gate terminal of the fourth PMOS transistor 241 are coupled to the second source/drain terminal of the third PMOS transistor 239 and the second source/drain terminal of the first NMOS transistor 231, respectively. The second source/drain terminal of the fourth PMOS transistor 241 is coupled to the post-shifting voltage VPPIN.

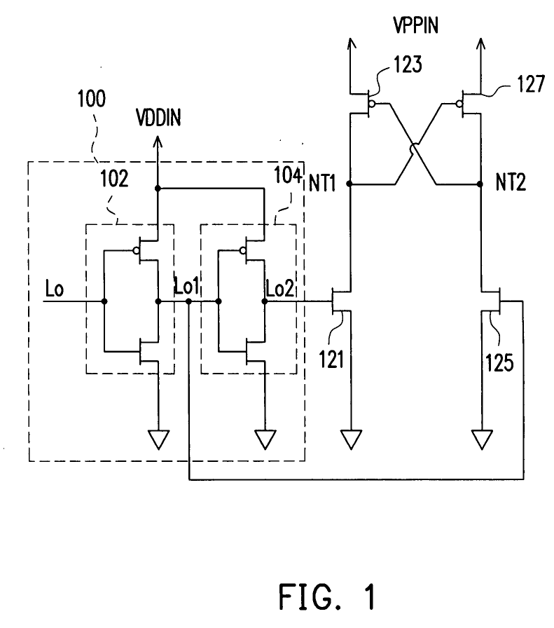

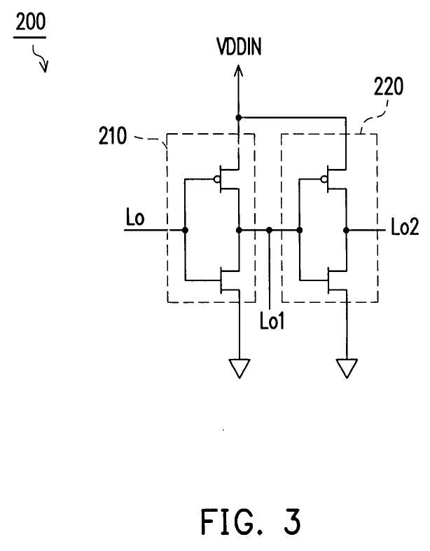

FIG. 3 is a circuit drawing showing a buffer circuit according to an embodiment of the present invention. With reference to FIG. 3, the buffer circuit 200 comprises a first inverter 210 and a second inverter 220 which are connected in series. The first inverter 210 receives the input signal Lo, outputting the first buffer output signal Lo1, which is reverse to the input signal Lo. The second inverter 220 receives the first buffer output signal Lo1 outputted from the first inverter 210, outputting the second buffer output signal Lo2. The operation of the buffer circuit is similar to that of the buffer circuit 100 in FIG. 1. Detailed descriptions are not repeated.

With reference to FIGS. 2 and 3, when the input signal Lo is at high state, the first buffer output signal Lo1 is at low state, and the second buffer output signal Lo2 is at high state. The first NMOS transistor 231 and the third PMOS transistor 239 are both turned on, and the second NMOS transistor 237 is turned off. When the first NMOS transistor 231 is turned on, the second source/drain terminal of the first NMOS transistor 231 is grounded. The first level-shifting signal NT1 is pulled down to low state. During the pull-down, the turned-on first PMOS transistor 233 is turned off soon because the gate voltage of the first PMOS transistor 233 is the pre-shifting voltage VDDIN. Accordingly, the pull-down of the first level-shifting signal NT1 is not affected by the first NMOS transistor 231, and the fourth PMOS transistor 241 is turned on. Because the third PMOS transistor 239 and the fourth PMOS transistor 241 are turned on simultaneously, the voltage of the second source/drain terminal of the second NMOS transistor 237 is pulled up to the post-shifting voltage VPPIN, outputting the second level-shifting signal NT2 with high-state, i.e. the post-shifting voltage VPPIN. Accordingly, the second buffer output signal Lo2 with the pre-shifting voltage VDDIN is transformed into the second level-shifting signal NT2 with the post-shifting voltage VPPIN.

After the input signal Lo is transformed into low state, the first buffer output signal is transformed into high state. The second buffer output signal Lo2 is transformed into low state. The first NMOS transistor 231 is turned off, and the first PMOS transistor 233 and the second NMOS transistor 237 are turned on. Though the fourth PMOS transistor 241 is on, the third PMOS transistor 239 is turned off soon while the second level-shifting signal NT2 is pulled down. Accordingly, the turn-on of the second NMOS transistor 237 will not be affected by the turn-on of the fourth PMOS transistor 241. Even if the input signal Lo is interrupted by signal interference which may alter the turn-on or turn-off of the second NMOS transistor 237, the second level-shifting signal NT2 is not affected. When the second level-shifting signal NT2 is pulled down to low state, the second PMOS transistor 235 is turned on. Because the first PMOS transistor 233 and the second PMOS transistor 235 are turned on simultaneously, the voltage of the first level-shifting signal NT1 is pulled up to the post-shifting voltage VPPIN.

In this embodiment, the state of the input signal Lo is pulled down from high state to low state. One of ordinary skill in the art can infer the situation when the state of the input signal Lo is pulled up from low state to high state and understand that the turn-on of the first NMOS transistor 231 will not affect the first level-shifting signal NT1.

In some embodiments, the level shifter of the present invention further comprises a first output buffer circuit and a second output buffer circuit. The first output buffer circuit receives the first level-shifting signal NT1 and outputs the first output signal H1 with a same phase with the first level-shifting signal NT1. The second output buffer circuit receives the second level-shifting signal NT2 and outputs the second output signal H2. The first and the second output signals vary within a range of the post-shifting voltage VPPIN.

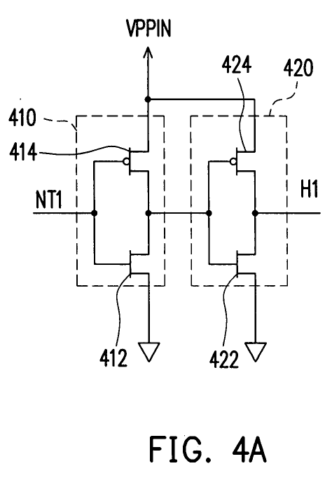

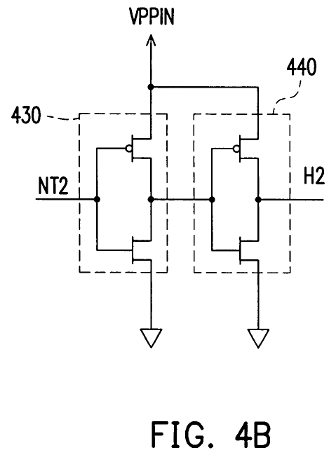

FIG. 4A is a circuit drawing showing a first output buffer circuit according to an embodiment of the present invention. With reference to FIG. 4A, the first output buffer circuit comprises a first output inverter 410 and a second output inverter 420, which are connected in series. The first output inverter 410 receives the first level-shifting signal NT1 and outputs the inverted first level-shifting signal NT1 to the second output inverter 420. The second output inverter 420 receives the inverted first level-shifting signal NT1 and outputs the first output signal H1.

With reference to FIG. 4A, the first output inverter comprises an NMOS transistor 412 and a PMOS transistor 414. A gate terminal of the NMOS transistor 412 receives the first level-shifting signal NT1. A second source/drain terminal of the NMOS transistor 412 is grounded. A gate terminal of the PMOS transistor 414 is coupled to the gate terminal of the NMOS transistor 412. A first source/drain terminal of the PMOS transistor 414 is coupled to the second source/drain terminal of the NMOS transistor 412. A second source/drain terminal of the PMOS transistor 414 is coupled to the post-shifting voltage VPPIN. The second output inverter 420 comprises an NMOS transistor 422 and a PMOS transistor 424. A gate terminal of the NMOS transistor 422 receives the inversed first level-shifting signal NT1. A first source/drain terminal of the NMOS transistor 422 is grounded. A gate terminal of the PMOS transistor 424 is coupled to the gate terminal of the NMOS transistor 422. A first source/drain terminal of the PMOS transistor 424 is coupled to the second source/drain terminal of the NMOS transistor 422. A second source/drain terminal of the PMOS transistor 424 is coupled to the second source/drain terminal of the PMOS transistor 414. In this embodiment, the operation of the first output buffer circuit is similar to that of the buffer circuit 100 in FIG. 1. Detailed descriptions are not repeated.

FIG. 4B is a circuit drawing showing a second output buffer circuit according to an embodiment of the present invention. With reference to FIG. 4B, the second output buffer circuit comprises a third output inverter 430 and a fourth output inverter 440, which are connected in series. The third output inverter 430 receives the second level-shifting signal NT2 and outputs the inverted second level-shifting signal NT2 to the fourth output inverter 440. According to the second level-shifting signal NT2, the fourth output inverter 440 receives the inverted second level-shifting signal NT2 and generates a second output signal H2. In this embodiment, the structure and operation of the second output buffer circuit is similar to those of the first output buffer circuit in FIG. 4A. Detailed descriptions are not repeated.

Accordingly, the present invention has at least the following advantages:
1. The level shifter of the present invention comprises the first and the third PMOS transistors. With these PMOS transistors, the first and the second level-shifting signals will not be affected or altered by the turn-on or turn-off of the first and the second NMOS transistors.

2. The level shifter of the present invention comprises the first and the third PMOS transistors. Even if the input signal is interrupted by signal interference, the first and the second level-shifting signals will not be affected.
3. By adding the first and the third PMOS transistors in the level shifter of the present invention, the impact of signal interference on the first and the second level-shifting signals can be substantially reduced, without increasing costs and the complicating the circuit design.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A level shifter, comprising:
a buffer circuit for receiving an input signal and outputting a first buffer output signal and a second buffer output signal, which is reverse to the first buffer output signal, wherein the first and the second buffer output signals vary within a range of a pre-shifting voltage;
a first NMOS transistor, a gate terminal of the first NMOS transistor receiving the second buffer output signal, and a first source/drain terminal of the first NMOS transistor being grounded;
a first PMOS transistor, a gate terminal of the first PMOS transistor being coupled to the gate terminal of the first NMOS transistor, and a first source/drain terminal of the first PMOS transistor being coupled to a second source/drain terminal of the first NMOS transistor, outputting a first level-shifting signal;
a second PMOS transistor, a first source/drain terminal of the second PMOS transistor being coupled to a second source/drain terminal of the first PMOS transistor, and a second source/drain terminal of the second PMOS transistor being coupled to a post-shifting voltage, which is not equal to the pre-shifting voltage;
a second NMOS transistor, a gate terminal of the second NMOS transistor receiving the first buffer output signal, and a first source/drain terminal of the second NMOS transistor being grounded;
a third PMOS transistor, a gate terminal of the third PMOS transistor being coupled to the gate terminal of the second NMOS transistor, and a first source/drain terminal of the third PMOS transistor being coupled to a second source/drain terminal of the second NMOS transistor and the gate terminal of the second PMOS transistor, outputting a second level-shifting signal, wherein the first and the second level-shifting signals vary within a range of the post-shifting voltage; and
a fourth PMOS transistor, a first source/drain terminal of the fourth PMOS transistor being coupled to a second source/drain terminal of the third PMOS transistor, a second source/drain terminal of the fourth PMOS transistor being coupled to the post-shifting voltage, and a gate terminal of the fourth PMOS transistor being coupled to the second source/drain terminal of the first NMOS transistor.

2. The level shifter of claim 1, wherein the buffer circuit comprises:
a first input inverter for receiving the input signal and outputting the first buffer output signal; and
a second input inverter for receiving the first buffer output signal and outputting the second buffer output signal.

3. The level shifter of claim 2, wherein the first input inverter comprises:
an NMOS transistor, a gate terminal of the NMOS transistor receiving the input signal, a first source/drain terminal of the NMOS transistor being grounded, and a second source/drain terminal of the NMOS transistor outputting the first buffer signal; and
a PMOS transistor, a first source/drain terminal of the PMOS transistor being coupled to the second source/drain terminal of the NMOS transistor, a second source/drain terminal of the PMOS transistor being coupled to the pre-shifting voltage, and a gate terminal of the PMOS transistor being coupled to the gate terminal of the NMOS transistor.

4. The level shifter of claim 2, wherein the second input inverter comprises:
an NMOS transistor, a gate terminal of the NMOS transistor receiving the first buffer output signal, a first source/drain terminal of the NMOS transistor being grounded, and a second source/drain terminal of the NMOS transistor outputting the second buffer output signal; and
a PMOS transistor, a first source/drain terminal of the PMOS transistor being coupled to the second source/drain terminal of the NMOS transistor, a second source/drain terminal of the PMOS transistor being coupled to the pre-shifting voltage, and a gate terminal of the PMOS transistor being coupled to the gate terminal of the NMOS transistor.

5. The level shifter of claim 1, further comprising:
a first output buffer circuit for receiving the first level-shifting signal and outputting a first output signal with a same phase with the first level-shifting signal, the first output buffer circuit comprising:
a first output inverter, receiving the first level-shifting signal and outputting an inversed first level-shifting signal; and
a second output inverter, receiving the inversed first level-shifting signal and outputting a first output signal; and
a second output buffer for receiving the second level-shifting signal and outputting a second output signal with a same phase with the second level-shifting signal, the second output buffer comprising:
a third output inverter, receiving the second level-shifting signal and outputting an inversed second level-shifting signal; and
a fourth inverter, receiving the inversed second level-shifting signal and outputting the second output signal.

6. The level shifter of clam 5, wherein the first output inverter comprises:
an NMOS transistor, a gate terminal of the NMOS transistor receiving the first level-shifting signal, a first source/drain terminal of the NMOS transistor being grounded, and a second source/drain terminal of the NMOS transistor outputting the inversed first level-shifting signal; and
a PMOS transistor, a gate terminal of the PMOS transistor being coupled to the gate terminal of the NMOS transistor, a first source/drain terminal of the PMOS transistor being coupled to the second source/drain terminal of the NMOS transistor, and a second source/drain terminal of the PMOS transistor being coupled to the post-shifting voltage.

7. The level shifter of claim 5, wherein the second output inverter comprises:
an NMOS transistor, a gate terminal of the NMOS transistor receiving the inversed first level-shifting signal, a first source/drain terminal of the NMOS transistor being grounded, and a second source/drain terminal of the NMOS transistor outputting the first output signal; and
a PMOS transistor, a gate terminal of the PMOS transistor being coupled to the gate terminal of the NMOS transistor, a first source/drain terminal of the PMOS transistor being coupled to the second source/drain terminal of the NMOS transistor, and a second source/drain terminal of the PMOS transistor being coupled to the post-shifting voltage.

8. The level shifter of claim 5, wherein the third output inverter comprises:
an NMOS transistor, a gate terminal of the NMOS transistor receiving the second level-shifting signal, a first source/drain terminal of the NMOS transistor being grounded, and a second source/drain terminal of the NMOS transistor outputting the inversed second level-shifting signal; and
a PMOS transistor, a gate terminal of the PMOS transistor being coupled to the gate terminal of the NMOS transistor, a first source/drain terminal of the PMOS transistor being coupled to the second source/drain terminal of the NMOS transistor, and a second source/drain terminal of the PMOS transistor being coupled to the post-shifting voltage.

9. The level shifter of claim 5, wherein the fourth output inverter comprises:
an NMOS transistor, a gate terminal of the NMOS transistor receiving the inversed second level-shifting signal, a first source/drain terminal of the NMOS transistor being grounded, and a second source/drain terminal of the NMOS transistor outputting the second output signal; and
a PMOS transistor, a gate terminal of the PMOS transistor being coupled to the gate terminal of the NMOS transistor, a first source/drain terminal of the PMOS transistor being coupled to the second source/drain terminal of the NMOS transistor, and a second source/drain terminal of the PMOS transistor being coupled to the post-shifting voltage.

10. The level shifter of claim 5, wherein the first output signal and the second output signal vary within a range of the post-shifting voltage.
